(19) United States
(12) Patent Application Publication
(10) Pub. No.: US 2007/0207260 A1
(43) Pub. Date: Sep. 6, 2007

(54) Coating plant and associated coating process

(75) Inventors: Andreas Collmer, Stuttgart (DE); Wilhelm Hofmann, Stuttgart (DE)

Correspondence Address: YOUNG & BASILE, P.C., 3001 WEST BIG BEAVER ROAD, SUITE 624, TROY, MI, 48084, US

(73) Assignee: DURR SYSTEMS INC., Auburn Hills, MI (US)

(21) Appl. No.: 11/681,603

(22) Filed: Mar. 2, 2007

Related U.S. Application Data
(60) Provisional application No. 60/778,342, filed on Mar. 2, 2006.

(51) Int. Cl. B05C 11/00; C23C 16/52

(52) U.S. Cl. 427/8; 118/683; 118/692; 118/712

(57) ABSTRACT

The invention concerns a coating plant for the coating of construction units with a coating medium, in particular a paint system for the lacquer finish of motor vehicle body parts, with a dosing pump, the coating medium supplied with a certain delivery (Fₘ) proportioned, and a pressure control valve arranged upstream before the dosing pump to adjust a coating medium pressure (p v) at the entrance of the dosing pump, as well as a control unit to adjust the pressure control valve a controlled variable of the pressure difference (Δp) through the dosing pump independently of the delivery of the dosing pump and the changing viscosity of the lacquers to an essentially constant desired value (Δp_{TARGET}).

### CROSS-REFERENCE TO RELATED APPLICATIONS

This application claims the benefit of the provisional patent application 60/778,342 for COATING PLANT AND ASSOCIATED COATING PROCESS, filed on Mar. 2, 2006 which is incorporated by reference herein its entirety. This claim is made under 35 U.S.C. § 119(e); 37 C.F.R. § 1.78; and 65 FR 50093.

### FIELD OF THE INVENTION

The invention concerns a coating plant for the coating of construction units with a coating medium, in particular a paint system for the lacquer finish of motor vehicle body parts as well as an associated operating procedure in accordance with the operating requirements.

### BACKGROUND

From EP 1,287,900 A2 and from “Technical Manual Color Volume Control”, page 32 (1994) of the company DRY a coating plant is well-known including a color print automatic controller and a dosing pump supplying a rotation atomizer with coating medium. Pressure sensors measure the coating medium pressure before and behind the dosing pump and supply an electronic control interacting with the color print automatic controller through a pressure controller valve designed as a proportional valve. With this well-known coating plant, a controlled variable regulates either the initial pressure of the color print automatic controller or the color flow rate.

Unfavorably the well-known coating plant is however subject to the construction unit wear of the dosing pump and the color print automatic controller, which leads to a short service life of these construction units. This applies in particular to the color print automatic controller, whose sealing ring experiences very strong washing after a certain actual working time.

Beyond that, dosing inaccuracies can occur with the conventional coating plants, which lead in extreme cases to a lacquer overspray and/or underspray, which expresses itself on the construction units being coated as a coating error.

### SUMMARY

One embodiment of the invention is to improve the initially described well-known coating plant.

This embodiment can include a coating plant and an associated operating procedure.

The invention is based on the technical realization that the construction unit load of the dosing pump and the color print automatic controller causes strong variations in pressure differentials or drops through the dosing pump during the coating process. This leads to a large positive pressure difference where the pressure before the dosing pump is larger than the pressure behind the dosing pump resulting in a pump slip and a higher discharge rate than desired with small changes of flow rate (so-called “Brushes”). With a negative pressure difference where the pressure before the dosing pump is smaller than the pressure behind the dosing pump, the fluctuations of the pressure difference lead to an interruption of the necessary lacquer volume, which causes the disturbing lacquer downstream errors (i.e. underspray and/or overspray) in the worst case. Beyond that the fluctuations of the pressure difference through the dosing pump contribute also to the unwanted mechanical load of the dosing pump and the color print automatic controller.

The pressure difference through the dosing pump, and thus disturbing dosing inaccuracies and mechanical loads, are not only affected by the varying quantity of the delivered coating medium. Rather, the pressure difference changes with a change to a coating medium with another viscosity, or with an installation of another color print automatic controller with another pressure speed ratio.

The invention covers therefore the general technical teaching of keeping as constant as possible the pressure differential through the dosing pump during the coating process independently of the delivered coating quantity, the viscosity of the coating medium, and/or the pressure speed ratio of the assigned color print automatic controller in order to avoid negative effects on the dosing accuracy and the service life of the assigned construction units.

The coating plant according to an embodiment of the invention includes a control unit, which interacts with the pressure control valve to adjust as a controlled variable the pressure difference through the dosing pump, independently of the delivery of the dosing pump, to an essentially constant desired value. With this embodiment of the invention, the pressure difference through the dosing pump is the controlled variable, whereas with the initially described state of the art the initial pressure of the pressure control valve and/or the color flow rate was regulated.

A control unit automatically maintains a constant differential pressure through the dosing pump, i.e. without a measurement and a feedback of the actual value of the pressure difference. Controlling the pressure difference, as compared to regulation of the pressure difference, provides favorable results with respect to minimizing oscillation inclination, simple technical realization, fast reaction to pressure jumps and color quantity alterations, and making compensation for dead time of the proportional valve possible.

The possibility exists in the context of the invention of regulating the pressure difference through the dosing pump by a control unit. This means that the actual value of the pressure difference through the dosing pump is measured and an automatic controller is supplied, which then the color print automatic controller, in order to regulate the pressure difference through the dosing pump to the desired value. An automatic controller can for example be a conventional PID automatic controller, however different automatic controller types can also be applicable in the context of the invention.

Furthermore the possibility exists of combining a regulation with a control, in the context of the invention, as the regulation overlays, for example with a pilot control, which interconnects the advantages of the regulation on the one hand and the control on the other hand.

In one embodiment of the invention, the automatic control of constant pressure difference through the dosing pump is a so-called parameter control, i,e. no regulation, so that the actual value of the pressure difference through the dosing pump does not have to be measured,

For this embodiment a first pressure sensor is used in the example of the invention, which measures the coating medium pressure downstream of the dosing pump, i.e. at the exit of the dosing pump. The measured coating medium pressure at the exit of the dosing pump is supplied to the control unit which interacts with the pressure control valve in such a way to operate as a function of the coating medium pressure measured downstream of the dosing pump according to a given control behavior so that the pressure difference through the dosing pump keeps the desired value constant.

The control of the pressure control valve by the control unit is made in the example of the invention indirectly by an inserted, connected in series, proportional valve. The proportional valve interacts with the control unit electrically and interacts with the color print automatic controller pneumatically.

Preferably the control behavior of the control unit is given by an essentially linear control characteristic, whereby the control characteristic defines the connection between the pressure and the interaction with size for the pressure control valve and/or that the resulting pressure measured at the exit of the dosing pump, defines the connection between the pressure and the inserted, connected in series, proportional valve. The linear control characteristic includes an axis intercept value and an upward gradient, whereby the axis intercept value is fixed as a function of the desired value of the pressure difference through the dosing pump and the actual pressure speed ratio of the system from the proportional valve and the color print automatic controller, while the upward gradient of the control characteristic is a function of the speed ratio of the system from the proportional valve and the pressure control valve. To the control characteristic the following formula applies:
kd=k1+k2·p_{H}
with
kd: Control size for the control of the proportional valve
pH: measured pressure behind the dosing pump
k1: Axis intercept value of the control characteristic
k2: Upward gradient of the control characteristic.

The control parameters k1 and k2 of the control characteristic are adjusted as follows, in order to provide the desired pressure difference through the dosing pump:

$$k 1 = \frac{Δ {p}_{Soll}}{η}$$

$$k 2 = \frac{1}{η}$$

with
Δp_{Soll} Desired value of the difference of pressure over the dosing pump,
π Speed ratio of the system from the pressure control valve and the upstream proportional valve.

During an adjustment of the control parameters k1, k2 on those values managing independently the desired pressure difference through the dosing pump during the delivery, results from the following formula:

$$\begin{matrix}Δ p = {p}_{V} - {p}_{H} \\ = η \cdot kd - {p}_{H} \\ = η \cdot ( k 1 + k 2 \cdot {p}_{H} ) - {p}_{H} \\ = η \cdot k 1 + ( η \cdot k 2 - 1 ) \cdot {p}_{H} \\ = Δ {p}_{Soll}\end{matrix}$$

The accurate adjustment of the optimal control parameters k1, k2 sets the knowledge of the speed ratio π ahead of the system from the proportional valve and the pressure control valve. With an exchange of the pressure control valve or with a change to a coating medium with another viscosity, the speed ratio π is not known, so that the control parameters k1, k2 must be determined. Preferably the determination of the control parameters k1 and k2 takes place in the context of an adaptation, whereby also the coating medium pressure is measured and evaluated upstream of the dosing pump. The adaptation of the control behavior takes place then via an adaptation unit, which is connected with the two pressure sensors at the input side and which adapts control behavior of the control unit as a function of the measured coating medium pressure upstream of the dosing pump and the measured coating medium pressure downstream of the dosing pump.

Preferably the adaptation of the control behavior of the control unit takes place iteratively and/or recursively. An iterative adaptation of the control behavior means that the control behavior, successively in multiple steps, appropriately becomes the optimal control behavior, which is necessary, in order to keep the pressure difference through the dosing pump constant. A recursive adaptation in the sense according to invention means that from the current control behavior of the control unit an improved control behavior is computed in each case.

The adaptation of the control behavior of the control unit can take place during the normal coating process or in separate adaptation phases. Beyond that the adaptation can take place during the normal coating process constantly or at certain time intervals.

### BRIEF DESCRIPTION OF THE DRAWINGS

The description herein makes reference to the accompanying drawings wherein like reference numerals refer to like parts throughout the several views, and wherein:

FIG. 1 is a schematic representation of a coating plant according to one embodiment of the invention;

FIG. 2 is a simplified schematic flow diagram of the adaptation procedure according to one embodiment of the invention for the adjustment of the control behavior.

FIG. 3 is a graph of time versus pressure; and

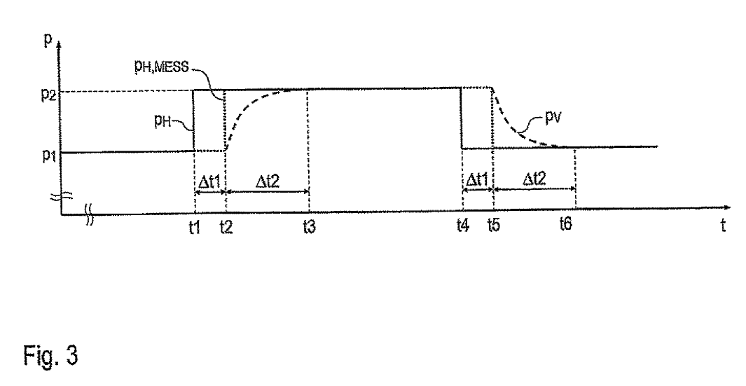

FIG. 4 is a graph of pressure verses electrical control signal.

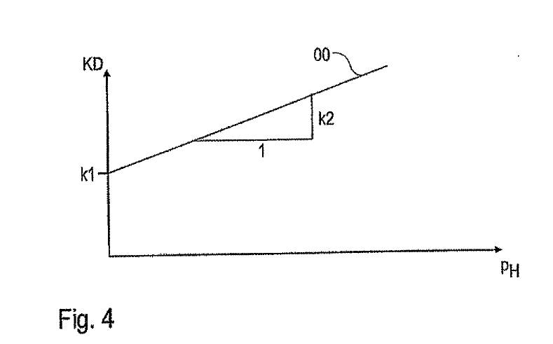

### DETAILED DESCRIPTION

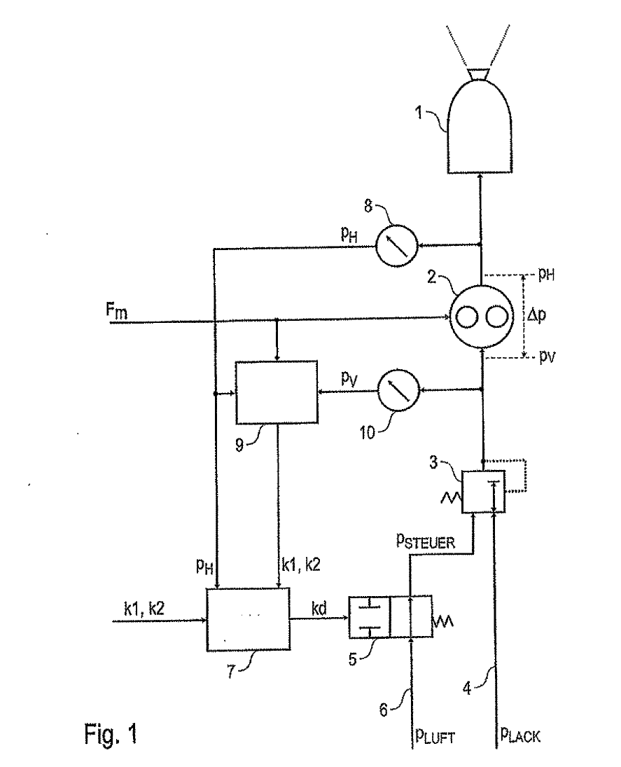

The coating plant according to one embodiment of the invention is represented schematically in FIG. 1 agrees partly with the initially described state of the art in accordance with EP 1,287,900 A2 and illustrates a conventional atomizer 1, which is supplied via a volumetric working dosing pump 2 with lacquer whereby the dosing pump 2 is attached through a color print automatic controller 3 to a color line 4, which interacts with a color print pressure sensor (p≈_{lacquer}) 8.

The color print automatic controller 3 can be configured in conventional way, which is described for example in EP 1,376,289 A1, which is incorporated by reference herein in its entirety.

In operation the color print automatic controller 3, at the entrance of the dosing pump 2, regulates a color print pressure pᵥ as a function of an actuating pressure pₛₜₑᵤₑᵣ, which the color print automatic controller 3 is supplied by a proportional valve 5, whereby the proportional valve 5 is attached to a control air line 6, which interacts with a control air pressure sensor (p≈_{AIR}) 10.

The proportional valve 5 is controlled by a control unit 7 with an electrical control signal kd, whereby the system from the proportional valve 5 and the color print automatic controller 3 exhibits a speed ratio π=pᵥ/kd, i.e, with a control of the proportional valve 5, the electrical control signal kd provides at the exit of the color print automatic controller 3 a coating medium pressure pᵥ=kd·π.

During the control of the proportional valve 5, the control unit considers the coating medium pressure p_{H} at the exit of the dosing pump 2, whereby the pressure p_{H} is measured by a pressure sensor 8. The control of the proportional valve 5 by the control unit 7 takes place then according to the following linear control characteristic:
kd=k1+k2·p_{H}
The control parameters k1 and k2 are as follows thereby:

$$k 1 = \frac{Δ {p}_{Soll}}{η}$$

$$k 2 = \frac{1}{η}$$

During such an optimal attitude of the control parameters k1, k2 then the desired pressure difference Δp_{Soll} produced the dosing pump 2, becomes from the following derivation:

$$\begin{matrix}Δ p = {p}_{V} - {p}_{H} \\ = η \cdot kd - {p}_{H} \\ = η \cdot ( k 1 + k 2 \cdot {p}_{H} ) - {p}_{H} \\ = η \cdot k 1 + ( η \cdot k 2 - 1 ) \cdot {p}_{H} \\ = Δ {p}_{Soll}\end{matrix}$$

The determination of the optimal values of the control parameters k1 and k2 requires knowledge of the speed ratio π of the system from the proportional valve 5 and the color print automatic controller 3. After an exchange of the color print automatic controller 3 by another color print automatic controller with another pressure speed ratio π the control parameters k1, k2 must be adapted to the changed pressure speed ratio of the color print automatic controller 3. Also with a change of the assigned coating medium and a change of the viscosity of the coating medium due to changes in the speed ratio π, likewise makes an adjustment of the control parameters k1, k1 necessary.

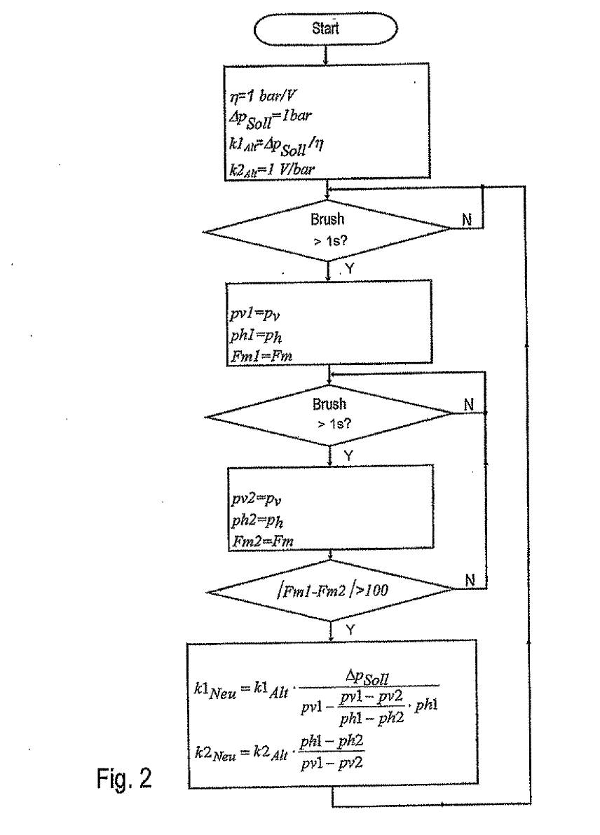

The coating plant according to one embodiment of the invention includes an adaptation unit 9, which is connected with the pressure sensor 8 and measures a further pressure sensor 10 of the coating medium pressure p, before the dosing pump 2. The adaptation unit 9 adjusts the control parameters k1, k2 in the context of an adaptation procedure, that in FIG. 2 is represented in the form of a flow chart.

With the first adaptation of the control parameters first the values for the speed ratio, π the desired value becomes Δp_{Soll} for the difference through the dosing pump 2 and the initial values k1ₐₗₜₒ and k2ₐₗₜₒ initialize for the control parameters k1 and k2, whereby the defaults on assumptions of the speed ratio π are based.

Subsequently, a so-called Brush or coating medium application process has been waiting, which lasts longer than one second. It concerns a change of flow rate in delivered coating averaging one, to which an opening is based to the main needle of the atomizer 1. The consideration of only relatively long persisting Brushes (or coating medium application process) with a length of time of 1 second is meaningful, since the length of time of shorter Brushes is not sufficient in order to let transients on engagement fade away.

Subsequently, the adaptation unit 9 measures over the two pressure sensors 8, 10, the pressure pV1 before the dosing pump 2 and the pressure pH1 behind the dosing pump 2. Beyond that the adaptation unit 9, in this first operating point, seizes also the color quantity of Fm1. The values pV1, pV2, and Fm1 are available here in the control anyway and do not have to be additionally measured.

Subsequently, the next Brush or coating medium operation process has been waiting, which lasts longer than one second and is not concerned therefore with transients on engagement.

In this second operating point, then again the values from the control that are selected and stored become pV2, pH2 and Fm2 for the pressure p before the dosing pump 2, the pressure p H behind the dosing pump 2 and the color quantity of Fₘ. Also here it can be used that the values pV2, pH2 and Fm2 available and therefore do not need to be additionally measured.

Then becomes examined whether the two operating points are sufficiently far from each other, in order to make a meaningful measurement possible. For this comparison, the absolute value of the difference between Fm1 and Fm2 of the measured color quantities are consulted for the adaptation of operating points in an educated manner and with a minimum value. If the formed distance between the two operating points is too small, the second operating point is rejected.

Otherwise then k2ₐₗₜₒ becomes a computed from the past values k1ₐₗₜₒ, the control parameter optimized values k1 NEU, k2 NEU using the following formulas:

$$k {2}_{Neu} = k {2}_{Alt} \cdot \frac{{p}_{H 1} - {p}_{H 2}}{{p}_{V 1} - {p}_{V 2}}$$

$$k {1}_{Neu} = k {1}_{Alt} \frac{Δ {p}_{SOLL}}{{p}_{V 1} - \frac{{p}_{V 1} - {p}_{V 2}}{{p}_{H 1} - {p}_{H 2}} \cdot {p}_{H 1}}$$

Subsequently, the control unit 7 then with the optimized values k1_{NEU} and k2_{NEU} works the control parameter, whereby in Figure the adaptation of the process, in order to optimize and reach the control behavior of the control unit 7 that the pressure difference Δp through the dosing pump 2 is kept as close as possible to the given desired value Δp_{Soll}.

Those formulas for the adaptation of the control parameters k1, k2 result from the following mathematical-physical derivation.

Described first the behavior of the coating plant by the following equations:
kd=k1+k2·p_{H} (1)
pv=kdπ (2)
Δp=pᵥ−p_{H} (3)
with
kd: Control size for the control of the proportional valve 5,
pv measured pressure before the dosing pump 2,
P_{H}: measured pressure behind the dosing pump 2,
k1: Axis intercept value of the control characteristic,
k2: Upward gradient of the control characteristic,
Δp_{Soll} Desired value of the pressure difference through the dosing pump 2,
Δp actual value of the pressure difference of pressure through the dosing pump 2,
πSpeed ratio of the system from the pressure control valve 3 and the upstream proportional valve 5.

From the equations (1) and (2) follow:
pᵥ=(k1+k2·p_{H})·π (4)

Considering now two operating points with different color quantities of Fm1, Fm2 and different coating medium pressures pV1, pV2, pH1 and pH2 before and/or behind the—I dosing pump, then applies in accordance with equation (4) to these two operating points in each case:
pᵥ1=(k1+k2·p_{H}1) (5)
pᵥ2=(k1+k2·p_{H}1) (6)

From the equations (5) and (6) follow then for the control parameter

$$k 2 = \frac{{p}_{V 1} - {p}_{V 2}}{η \cdot ( {p}_{H 1} - {p}_{H 2} )} \qquad ( 7 )$$

For the old, non-optimized value k2ₐₗₜₒ, the control parameter k2 applies directly:

$$k {2}_{Alt} = \frac{{p}_{V 1} - {p}_{V 2}}{η \cdot ( {p}_{H 1} - {p}_{H 2} )} \qquad ( 8 )$$

For that new, optimized value k2_{NEU}, the control parameter k2 applies then with consideration of the equation (3), fulfilled with optimal control behavior.

$$k {2}_{Neu} = \frac{( {p}_{H 1} + Δ p ) - ( {p}_{H 2} + Δ p )}{η \cdot ( {p}_{H 1} - {p}_{H 2} )} \qquad ( 9 )$$

From the equations (8) and (9) follow then the adaptation formula for the adaptation of the control parameter k2:

$$k {2}_{Neu} = k {2}_{Alt} \cdot \frac{{p}_{H 1} - {p}_{H 2}}{{p}_{V 1} - {p}_{V 2}} . \qquad ( 10 )$$

Described the derivation of the adaptation formula for the control parameter k1 in the following one becomes now, from the equations (1) (2) and (3) follows:

$$k 1 = \frac{{p}_{V}}{η} - k 2 \cdot {p}_{H} \qquad ( 11 )$$

If one uses equation (6) in equation (11), then one obtains for the old, non-optimized value k1ₐₗₜₒ, of the control parameter k1 in the operating point 1 with pV1, pH1 and Fm1:

$$k {1}_{Alt} = \frac{{p}_{V 1}}{η} - \frac{{p}_{V 1} - {p}_{V 2}}{η \cdot ( {p}_{H 1} - {p}_{H 2} )} \cdot {p}_{H 1} \qquad ( 12 )$$

For that new adapted optimum value k1 NEU must apply against it:

$$k {1}_{Neu} = \frac{Δ {p}_{Soll}}{η} \qquad ( 13 )$$

From the equations (12) and (13) follow then finally the adaptation formula for the adaptation of the control parameter k1:

$$k {1}_{Neu} = k {1}_{Alt} \frac{Δ {p}_{SOLL}}{{p}_{V 1} - \frac{{p}_{V 1} - {p}_{V 2}}{{p}_{H 1} - {p}_{H 2}} \cdot {p}_{H 1}} \qquad ( 13 )$$

While the invention has been described in connection with what is presently considered to be the most practical and preferred embodiment, it is to be understood that the invention is not to be limited to the disclosed embodiments but, on the contrary, is intended to cover various modifications and equivalent arrangements included within the spirit and scope of the appended claims, which scope is to be accorded the broadest interpretation so as to encompass all such modifications and equivalent structures as is permitted under the law.

What is claimed is:

1. A coating plant for coating of construction units with a coating medium comprising:
a. a) a dosing pump supplying a coating medium with a certain delivery proportions;
b) a pressure control valve arranged upstream before the dosing pump to adjust pressure of the coating medium at the entrance of the dosing pump; and
c) a control unit interacts with the pressure control valve to adjust a pressure difference through the dosing pump independent of a delivery pressure of the dosing pump to an essentially constant desired value.

2. The coating plant of claim 1 further comprising:
a) a first pressure sensor measuring the coating medium pressure downstream behind the dosing pump; and
b) whereby the control unit interacts with the pressure control valve as a function of the coating medium pressure measured downstream behind the dosing pump according to a given control behavior, so that the pressure difference through the dosing pump achieves the desired value.

3. The coating plant of claim 2 further comprising that the control unit interacts with the pressure control valve as a function of the coating medium pressure measured downstream behind the dosing pump according to an essentially linear control characteristic.

4. The coating plant of claim 3 further comprising that the control characteristic exhibits a given axis intercept value (k1) and a given upward gradient (k2), whereby the axis intercept value (k1) corresponds to a given desired value of the pressure difference through the pressure control valve.

5. The coating plant of claim 1 further comprising:
a) a second pressure sensor measuring the coating medium pressure upstream before the dosing pump;
b) an adaptation unit connected to receive input from two pressure sensors to influence a control behavior of the control unit upstream before the dosing pump and the coating medium pressure downstream behind the dosing pump as a function of the coating medium pressure sensed by the two pressure sensors.

6. The coating plant of claim 5 further comprising that the adaptation unit influences the control behavior of the control unit at least one of iteratively and recursively.

7. The coating plant of claim 5 further comprising that the adaptation unit influences the control behavior of the control unit while a normal coating process takes place.

8. The coating plant of claim 5 further comprising that the adaptation unit influences the control behavior of the control unit constantly or in certain time intervals.

9. The coating plant of claim 1 further comprising that the control unit interacts with the pressure control valve directly without an automatic control loop inserted in series connection.

10. The coating plant of claim 1 further comprising that the given pressure difference through the dosing pump lies within a range of between approximately 0.5 bar and approximately 1.5 bar and/or that the pressure difference exhibits a tolerance field of +/− 1 bar.

11. The coating plant of claim 1 further comprising that the control unit heads for the pressure control valve over a proportional valve, whereby the control unit heads for the proportional valve electrically, while the proportional valve heads for the pressure control valve pneumatically.

12. The coating plant of claim 1 further comprising that the dosing pump feeds the application equipment with the coating medium.

13. The coating plant of claim 12 further comprising that the application equipment is a rotation atomizer.

14. The coating plant of claim 1 further comprising a paint system for a lacquer finish of motor vehicle body parts.

15. An operating procedure for a coating plant for coating of construction units with a coating medium comprising:
a) quantity dosage of the coating medium by a dosing pump according to a given delivery;
b) regulation of a coating medium pressure upstream before the dosing pump by a pressure control valve; and
c) controlling differential pressure drop through the dosing pump, as a controlled variable to a given desired value independently of a delivery quantity of the dosing pump.

16. The operating procedure of claim 15 further comprising:
a) measuring the coating medium pressure downstream behind the dosing pump by a first pressure sensor;
b) controlling the pressure control valve according to a given control behavior as a function of the coating medium pressure measured downstream behind the dosing pump; and
c) maintaining an essentially constant delivery quantity through the dosing pump while independently controlling the pressure difference through the pressure control valve.

17. The operating procedure of claim 16 further comprising that the pressure control valve interacts as a function of the coating medium pressure measured downstream behind the dosing pump according to an essentially linear control characteristic.

18. The operating procedure of claim 15 further comprising that the control characteristic exhibits a given axis intercept value (k1) and a given upward gradient (k2), whereby the axis intercept value (k1) of the control characteristic becomes specified according to a desired pressure difference through the pressure control valve.

19. The operating procedure of claim 15 further comprising:
a) measuring the coating medium pressure upstream before the dosing pump;
b) influencing the control behavior as a function of a combination of the measured coating medium pressure behind the dosing pump and the measured coating medium pressure before the dosing pump.

20. The operating procedure of claim 19 further comprising that the influence on the control behavior becomes one of iterative and recursively.

21. The operating procedure of claim 19 further comprising that the influence on the control behavior occurs during a normal coating process.

22. The operating procedure of claim 19 further comprising that the influence on the control behavior becomes one of constantly interacting and interacting at certain time intervals.

23. The operating procedure of claim 19 further comprising that the control behavior occurs after at least one of an exchange of the pressure control valve and a change of the coating medium.

24. The operating procedure of claim 19 further comprising that for the influencing of the control behavior considers only changes of delivery occurring over a certain minimum time period.

25. The operating procedure of claim 19 further comprising:
a) measuring the coating medium pressure before the dosing pump and the coating medium pressure behind the dosing pump with a first delivery of the dosing pump;
b) measuring the coating medium pressure before the dosing pump and the coating medium pressure behind the dosing pump with a second delivery of the dosing pump; and
c) influencing the control behavior of the control unit on the basis the coating medium pressures measured with the two deliveries before and behind the dosing pump.

26. The operating procedure of claim 15 further comprising that the control behavior considers as variable size exclusively the coating medium pressure measured downstream behind the dosing pump.

27. The operating procedure of claim 15 further comprising painting a lacquer finish for coating of motor vehicle body parts.
